(19) United States
(12) Patent Application Publication
(10) Pub. No.: US 2026/0190645 A1
(43) Pub. Date: Jul. 2, 2026

(54) DISPLAY PANEL AND ELECTRONIC DEVICE INCLUDING THE SAME

(71) Applicant: Samsung Display Co., Ltd., Yongin-Si (KR)

(72) Inventors: Soodong Son, Yongin-si (KR); Cheolhyeon Park, Yongin-si (KR); Yudong Jang, Yongin-si (KR); Juyeon Seo, Yongin-si (KR); Dongyoon So, Yongin-si (KR)

(21) Appl. No.: 19/407,452

(22) Filed: Dec. 3, 2025

(30) Foreign Application Priority Data
Dec. 31, 2024 (KR) 10-2024-0202727

(51) Int. Cl. H10K 59/122; H10K 59/131

(52) U.S. Cl. CPC H10K 59/122; H10K 59/131

(57) ABSTRACT

A display panel and an electronic device including the display panel are provided. The display panel includes a substrate including a display area and a peripheral area arranged to surround at least a portion of the display area, an insulating layer arranged on the substrate, a conductive layer arranged on the insulating layer and extending from the display area to the peripheral area, and an uneven layer arranged in the peripheral area and arranged on the conductive layer, wherein the conductive layer has at least one opening, a longest width of the one opening being greater than 0 μm and less than 40 μm.

### CROSS-REFERENCE TO RELATED APPLICATION

This application is based on and claims priority under 35 U.S.C. § 119 to Korean Patent Application No. 10-2024-0202727, filed on Dec. 31, 2024, in the Korean Intellectual Property Office, the disclosure of which is incorporated by reference herein in its entirety.

### BACKGROUND

### 1. Field

One or more embodiments relate to an apparatus, and more particularly, to a display panel and an electronic device.

### 2. Description of the Related Art

Mobility-based electronic devices are widely used. Tablet personal computers (PCs) have recently been widely used as mobile electronic devices in addition to small electronic devices such as mobile phones.

In order to support various functions, the mobile electronic device includes a display panel for providing a user with visual information such as images or video. Recently, as other components for driving a display panel become miniaturized, the proportion of the display panel in an electronic device is gradually increasing, and structures that are bendable from a flat state to have a preset angle are being developed.

### SUMMARY

Generally, when a metal layer is placed on an organic layer during the manufacture of a display panel, the metal layer placed on the organic layer may be lifted due to shrinkage of the organic layer. In this case, a space between the metal layer and the organic layer may occur, which may cause other materials not to be placed on the metal layer or not to be placed at the correct position, thereby causing a defect in the display panel. One or more embodiments include a display panel in which a metal layer is not lifted on an organic layer, and an electronic device including the display panel.

Additional aspects will be set forth in part in the description which follows and, in part, will be apparent from the description, or may be learned by practice of the presented embodiments of the disclosure.

According to one or more embodiments, a display panel includes a substrate including a display area and a peripheral area arranged to surround at least a portion of the display area, an insulating layer arranged on the substrate, a conductive layer arranged on the insulating layer and extending from the display area to the peripheral area, and an uneven layer arranged in the peripheral area and arranged on the conductive layer, wherein the conductive layer has at least one opening, a longest width of the at least one opening being greater than 0 μm and less than or equal to 40 μm.

A least a portion of the uneven layer may cover at least one the opening.

The at least one opening may include a plurality of openings, wherein the plurality of openings may be arranged in a row along a border of the display area.

The substrate may include a round area.

The display panel may further include a wiring arranged on the substrate and providing a common voltage.

The conductive layer may be electrically connected to the wiring.

The display panel may further include a plurality of sub-pixel electrodes arranged on the insulating layer and spaced apart from each other in the display area, a plurality of emission layers arranged on the plurality of sub-pixel electrodes, respectively, and an opposite electrode arranged on the plurality of emission layers and arranged over the entire display area, wherein the opposite electrode may be electrically connected to the conductive layer.

The display panel may further include a partition wall arranged in the peripheral area and arranged on an outer side of the uneven layer.

The display panel may further include an organic insulating layer arranged in the display area; and a bank layer arranged on the organic insulating layer and having an opening.

An end of the conductive layer may be disposed between the organic insulating layer and the bank layer.

The uneven layer may include a same material as the bank layer.

According to one or more embodiments, an electronic device includes a display panel, wherein the display panel includes a substrate including a display area and a peripheral area arranged to surround at least a portion of the display area, an insulating layer arranged on the substrate, a conductive layer arranged on the insulating layer and extending from the display area to the peripheral area, and an uneven layer arranged in the peripheral area and arranged on the conductive layer, wherein the conductive layer has at least one opening, a longest width of the at least one opening being greater than 0 μm and less than or equal to 40 μm.

A least a portion of the uneven layer may cover the at least one opening.

The at least one opening may include a plurality of openings, wherein the plurality of openings may be arranged in a row along a border of the display area.

The substrate may include a round area.

The display panel may further include a wiring arranged on the substrate and providing a common voltage.

The conductive layer may be electrically connected to the wiring.

The display panel may further include a plurality of sub-pixel electrodes arranged on the insulating layer and spaced apart from each other in the display area, a plurality of emission layers arranged on the plurality of sub-pixel electrodes, respectively, and an opposite electrode arranged on the plurality of emission layers and arranged over the entire display area, wherein the opposite electrode may be electrically connected to the conductive layer.

The display panel may further include a partition wall arranged in the peripheral area and arranged on an outer side of the uneven layer.

The display panel may further include a bank layer arranged on the substrate and having an opening, wherein the uneven layer may include a same material as the bank layer.

These and/or other aspects will become apparent and more readily appreciated from the following description of the embodiments, taken in conjunction with the accompanying drawings.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device according to an embodiment;

FIGS. 2 to 4 are schematic diagrams of electronic devices according to various embodiments;

FIG. 5 is a perspective view schematically illustrating an electronic device according to an embodiment;

FIG. 6 is an exploded perspective view schematically illustrating the electronic device of FIG. 5;

FIG. 7A is a plan view schematically illustrating a portion of a display apparatus shown in FIG. 6;

FIG. 7B is a side view schematically illustrating a portion of the display apparatus shown in FIG. 7A;

FIG. 8 is a plan view schematically illustrating a portion of the display apparatus shown in FIG. 6;

FIG. 9 is a circuit diagram schematically illustrating a sub-pixel circuit of a sub-pixel arranged in a display area shown in FIG. 8;

FIG. 10 is a plan view showing an enlargement of a part B of FIG. 8;

FIG. 11 is a cross-sectional view taken along line A-A′ of FIG. 10; and

FIG. 12 is a plan view showing openings according to embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and redundant descriptions thereof are omitted.

Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be further understood that the terms “including” or “having” used herein specify the presence of stated features or elements, but do not preclude the presence or addition of one or more other features or elements.

It will be further understood that, when a layer, region, or element is referred to as being “on” another layer, region, or element, it may be directly on the other layer, region, or element, or may be indirectly on the other layer, region, or element with intervening layers, regions, or elements therebetween.

Sizes of elements in the drawings may be exaggerated or reduced for convenience of descriptions. For example, as sizes and thicknesses of elements in the drawings are arbitrarily illustrated for convenience of descriptions, the disclosure is not limited thereto.

In the following embodiments, the x-axis direction (or x direction), the y-axis direction (or y direction) and the z-axis direction (or z direction) are not limited to directions corresponding to three axes of the rectangular coordinate system, and may be interpreted in a broader sense. For example, the x-axis direction (or x direction), the y-axis direction (or y direction), and the z-axis direction (or z direction) may be perpendicular to one another or may represent different directions that are not perpendicular to one another.

When a certain embodiment may be implemented differently, a particular process order may be different from the described order. For example, two consecutively described processes may be substantially simultaneously performed, or may be performed in an order opposite to the described order.

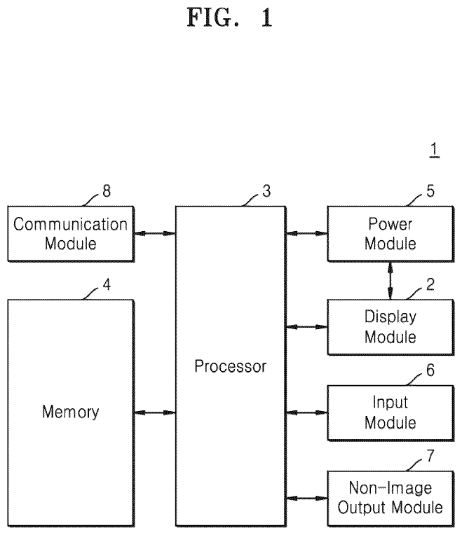

FIG. 1 is a block diagram of an electronic device 1 according to an embodiment.

Referring to FIG. 1, the electronic device 1 according to an embodiment may include a display module 2 including a display panel, a processor 3, a memory 4, and a power module 5.

The processor 3 may include at least one of a central processing unit (CPU), an application processor (AP), a graphic processing unit (GPU), a communication processor (CP), an image signal processor (ISP), and a controller. In an embodiment, the processor 3 may include at least two processors. For example, the processor 3 may include a main processor in the form of a first driving chip including a CPU, and an auxiliary processor in the form of a second driving chip including a controller configured to receive an image signal from the main processor and process the image signal to be adapted to an interface specification of the display module 2.

The memory 4 may include at least one of a non-volatile memory and a volatile memory. The memory 4 may store data information required for an operation of the processor 3 or the display module 2. When the processor 3 executes an application stored in the memory 4, an image data signal and/or an input control signal may be transmitted to the display module 2, and the display module 2 may process the provided signal, and thus, may output image information via a display screen.

The power module 5 may include a power supply module such as a power adaptor or a battery device, and a power conversion module for generating, by converting power supplied by the power supply module, power required for an operation of the electronic device 1. Power conversion by the power conversion module may include, but is not limited to, direct current (DC)-DC conversion, alternating current (AC)-DC conversion, and DC-AC conversion.

The electronic device 1 may further include an input module 6, a non-image output module 7, and/or a communication module 8.

The input module 6 may provide input information to the processor 3 and/or the display module 2. The input module 6 may include not only physical buttons, a keyboard, and a microphone but also include various sensor modules. An example of a sensor module may include not only a touch sensor, a pressure sensor, a distance sensor, a position sensor, a digitizer, a motion recognition sensor, a camera sensor, a light-receiving sensor, a photoelectric conversion sensor, and a temperature sensor but also include a biometric sensor including a blood pressure sensor, a blood glucose sensor, an electrocardiogram sensor, a heart rate sensor, etc.

The non-image output module 7 may provide a user with information by receiving the information other than an image transmitted from the processor 3. An example of the non-image output module 7 may include an audio module, a haptic module, a light-emitting module, etc., and may also include other functional module (e.g., a cooling module of a refrigerator) dedicated to an electronic device.

The communication module 8 is a module to handle information transmission and reception between the electronic device 1 and an external device, and may include a receiver and a transmitter. The communication module 8 may include various wireless communication modules including a mobile communication module, a wireless-fidelity (Wi-Fi) module, a Bluetooth module, etc., or various wired communication modules.

At least one of elements of the electronic device 1 may be included in a display apparatus according to embodiments. Also, some of separate modules functionally included in one module may be included in the display apparatus, and others may be provided separately from the display apparatus. For example, the display apparatus may include the display module 2, and the processor 3, the memory 4, and the power module 5 may be provided in the form of other devices in the electronic device 1, not in the display apparatus. As another example, the power module 5 may be arranged in the display apparatus, and may provide power to the processor 3 and the memory 4 arranged in the electronic device 1, which are not a portion of the display apparatus, but the disclosure is not limited thereto.

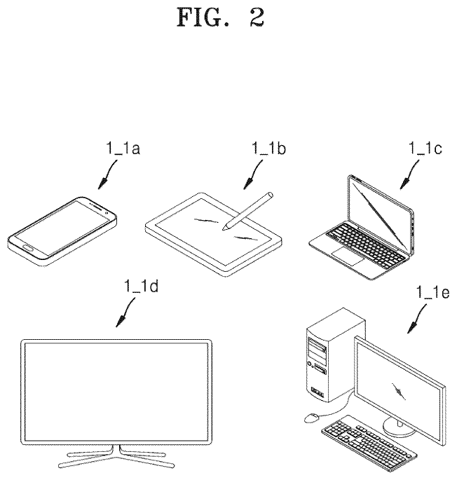

FIGS. 2 to 4 are schematic diagrams of an electronic device according to various embodiments. FIGS. 2 to 4 illustrate examples of various electronic devices to which display apparatuses according to embodiments are applied.

FIG. 2 illustrates a smartphone 1_1a, a tablet personal computer (PC) 1_1b, a laptop computer 1_1c, a television (TV) 1_1d, and a monitor for desktop PC 1_1e.

The smartphone 1_1a may include an input module including a touch sensor and a communication module as well as the display module. The smartphone 1_1a may process information received via the communication module or another input module, and thus, may display the information via a display module of a display apparatus.

Similar to the smartphone 1_1a, each of the tablet PC 1_1b, the laptop computer 1_1c, the TV 1_1d, and the monitor for desktop PC 1_1e may include a display module and an input module, and, in some cases, may further include a communication module.

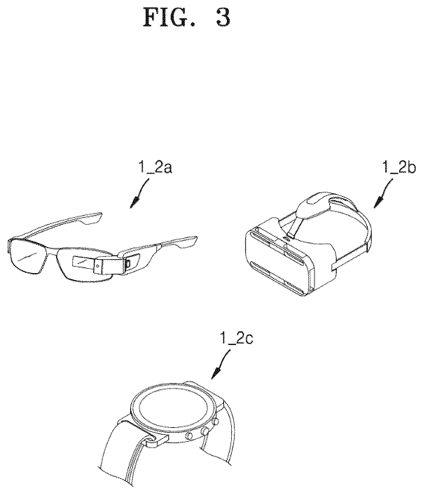

FIG. 3 illustrates an example in which an electronic device including a display module is applied to a wearable electronic device. The wearable electronic device may include smart glasses 1_2a, a head-mounted display 1_2b, a smart watch 1_2c, or the like.

Each of the smart glasses 1_2a and the head-mounted display 1_2b may include a display module for projecting a display image, and a reflector for reflecting a projected display image and providing the reflected display image to eyes of a user, and thus, may provide the user with an image of a virtual reality or an augmented reality.

The smart watch 1_2c may include a biometric sensor as an input device, and may provide, via a display module, a user with biometric information recognized via the biometric sensor.

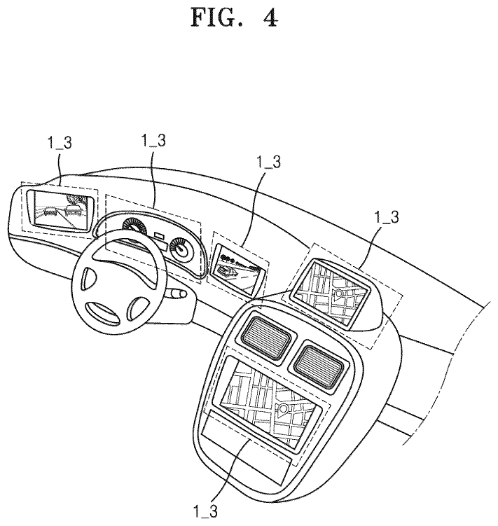

FIG. 4 illustrates an example in which an electronic device 1_3 including a display module is applied to a vehicle. For example, the electronic device 1_3 may be applied to a dashboard, a center console, etc. of the vehicle, or may be applied to a center information display (CID) arranged on the dashboard of the vehicle, a room mirror display replacing a side-view mirror of the vehicle, etc.

Although not illustrated, an electronic device to which a display apparatus according to embodiments is applied may include not only devices including an advertisement board, an electronic display board, a game player, etc. for mainly displaying a screen but also include various home appliances including a refrigerator, a washing machine, a dryer, an air conditioner, a robot cleaner, etc. for displaying information via a display module. Also, when a display module has a function for transmitting light, the display module may be applied to a smart window, or an electronic device including a transparent display apparatus through which both a background and a display image may be seen. Types of an electronic device according to embodiments are not limited to the examples, and application to other unstated various electronic devices may be possible.

Hereinafter, for convenience of descriptions, a case in which the electronic device 1 is a smartphone will be mainly described.

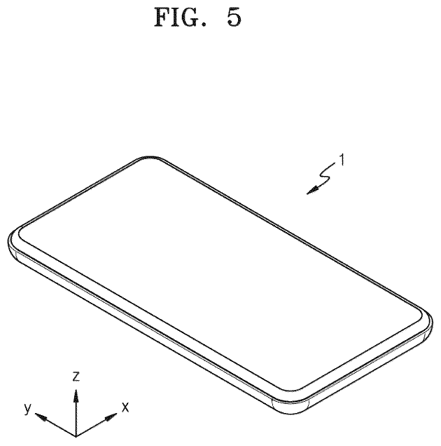

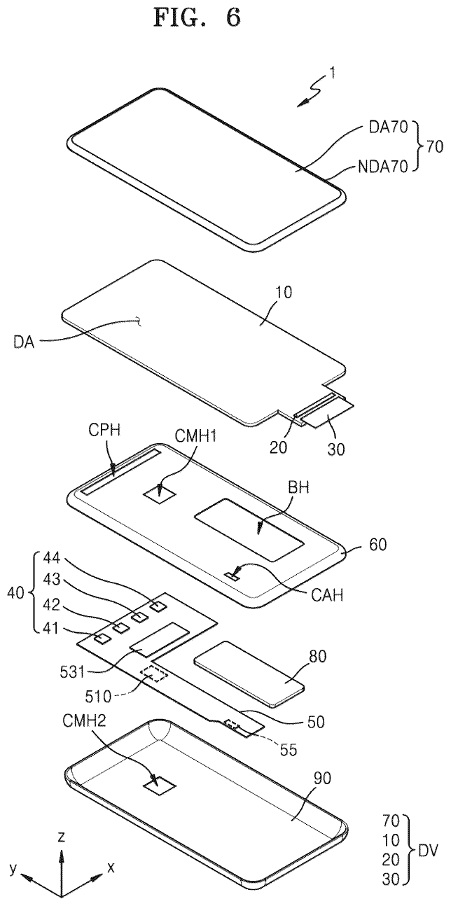

FIG. 5 is a perspective view schematically illustrating the electronic device 1 according to an embodiment. FIG. 6 is an exploded perspective view schematically illustrating the electronic device 1 of FIG. 5.

Referring to FIGS. 5 and 6, the electronic device 1 may include a display apparatus DV including a cover window 70, a display panel 10, a data driver 20, and a display circuit board 30, a component 40, a bracket 60, a main circuit board 50, a battery 80, and/or a lower cover 90.

In the specification, “left,” “right,” “upper,” and “lower” in a plan view refer to directions when the display panel 10 is viewed in a direction perpendicular to the display panel 10. For example, “left” refers to a −x direction, “right” refers to a +x direction, “upper” refers to a +y direction, and “lower” refers to a −y direction.

In a plan view, the electronic device 1 may have a substantially rectangular shape. For example, the electronic device 1 may have a substantially rectangular shape having a short side in an x-axis direction and a long side in a y-axis direction in a xy plane as shown in FIG. 5. In this case, a corner where the short side extending in the x-axis direction and the long side extending in the y-axis direction meet each other may form a right angle, or may have a rounded shape with a preset curvature. However, in a plan view, the electronic device 1 may have a polygonal shape other than a rectangular shape, and may also have an elliptical shape, or an irregular shape.

The cover window 70 may be arranged on the display panel 10 so as to cover a top surface of the display panel 10. The cover window 70 may protect the top surface of the display panel 10.

The cover window 70 may include a transmissive cover portion DA70 corresponding to the display panel 10 and a light-blocking cover portion NDA70 surrounding the transmissive cover portion DA70. The light-blocking cover portion NDA70 may include an opaque material for blocking light (e.g., a colored opaque material). The light-blocking cover portion NDA70 may include a pattern that may be shown to a user when an image is not displayed.

The display panel 10 may be arranged under the cover window 70. The display panel 10 may overlap the transmissive cover portion DA70 of the cover window 70. The display panel 10 includes a display area DA. The display area DA where an image is displayed may include an area (hereinafter, referred to as a component area) where light emitted from the component 40 arranged under the display panel 10 is transmitted. The component 40 may include a sensor or a camera using visible light, infrared light, or sound.

The display panel 10 may be a light-emitting display panel including a light-emitting diode. The light-emitting diode may be an organic light-emitting diode including an organic material as a light-emitting material, or an inorganic light-emitting diode including an inorganic material as a light-emitting material. The inorganic light-emitting diode may include a PN junction diode including inorganic semiconductor-based materials. When a voltage is applied to a PN junction diode in a forward direction, holes and electrons may be injected, and energy generated by recombination of the holes and electrons may be converted into light energy to emit light of a preset color. The inorganic light-emitting diode may have a width of several micrometers to hundreds of micrometers, or several to hundreds of nanometers. The inorganic light-emitting diode may be referred to as a micro LED.

The display panel 10 may be a rigid display panel that is rigid and is not easily bent, or a flexible display panel that is flexible and may be easily bent, folded, or rolled. For example, the display panel 10 may be a foldable display panel that may be folded and unfolded, a curved display panel with a curved display surface, a bended display panel in which an area other than a display surface is folded, a rollable display panel that may be rolled or unrolled, or a stretchable display panel.

The display panel 10 may be a transparent display panel that is transparent so that an object or a background arranged on a bottom surface of the display panel 10 is viewed from the top surface of the display panel 10. Alternatively, the display panel 10 may be a reflective display panel capable of reflecting an object or a background on the top surface of the display panel 10.

The data driver 20 may be mounted on the display panel 10 in the form of an integrated circuit (IC). However, the disclosure is not limited thereto, and for example, the data driver 20 may be mounted on the display circuit board 30.

The display circuit board 30 may be attached to one side of the display panel 10. The display circuit board 30 may be a flexible printed circuit board (FPCB) that is bendable, a rigid printed circuit board (PCB) that is rigid and is not bendable, or a composite printed circuit board including both the rigid PCB and the FPCB. A touch sensor driver may be mounted on the display circuit board 30. The touch sensor driver may be formed as an integrated circuit. The touch sensor driver may be electrically connected to touch electrodes of a touchscreen layer of the display panel 10 via the display circuit board 30.

The touchscreen layer of the display panel 10 may detect a touch input of the user by using at least one of various touch methods such as a resistive method or a capacitive method. When the touchscreen layer of the display panel 10 detects a touch input of the user by using a capacitive method, the touch sensor driver may apply driving signals to driving electrodes from among the touch electrodes, and may determine whether the user touches by detecting voltages charged in mutual capacitances (hereinafter referred to as “mutual capacitance”) between the driving electrodes and sensing electrodes via the sensing electrodes from among the touch electrodes.

A user's touch may include a contact touch and a proximity touch. The contact touch means that an object such as a user's finger or a pen directly contacts the cover window 70 arranged on the touchscreen layer. The proximity touch means that an object such as the user's finger or a pen is located close to the cover window 70, such as hovering. The touch sensor driver may transmit sensor data to a main processor 510 according to the detected voltages, and the main processor 510may calculate touch coordinates where the touch input occurs by analyzing the sensor data.

A controller for supplying driving voltages for driving sub-pixels of the display panel 10, a gate driver, and/or the data driver 20 may be arranged on the display circuit board 30.

The bracket 60 for supporting the display panel 10 may be arranged under the display panel 10. The bracket 60 may include plastic, metal, or both plastic and metal. The bracket 60 may include a first camera hole CMH1 into which a camera device 531 is inserted, a battery hole BH in which the battery 80 is arranged, a cable hole CAH through which a cable connected to the display circuit board 30 passes, and a component hole CPH disposed in an area corresponding to the components 40. The component hole CPH may expose the components 40 of the main circuit board 50 when viewed in a third direction (a z-axis direction). For reference, the display area DA of the display panel 10 may overlap the components 40 of the main circuit board 50 when viewed in the third direction (the z-axis direction). When necessary, the bracket 60 may not have the component hole CPH.

The components 40 included in the electronic device 1 may include a first component 41, a second component 42, a third component 43, and a fourth component 44 overlapping the display panel 10. Each of the first component 41, the second component 42, the third component 43, and the fourth component 44 may include at least one of a proximity sensor, an illumination sensor, an iris sensor, a facial recognition sensor, and a camera (or an image sensor). The proximity sensor using infrared rays may detect an object located close to a top surface of the electronic device 1, and the illuminance sensor may detect a brightness of light incident on the top surface of the electronic device 1. Also, the iris sensor may capture an image of the iris of a person located over the top surface of the electronic device 1, and the camera may obtain image data of the object arranged over the top surface of the electronic device 1. The component 40 is not limited to the proximity sensor, the illumination sensor, the iris sensor, the facial recognition sensor, and/or the camera, and may include another sensor.

The main circuit board 50 and the battery 80 may be arranged under the bracket 60. The main circuit board 50 may be a rigid printed circuit board or a flexible printed circuit board.

The main circuit board 50 may include the main processor 510, the camera device 531, a main connector 55, and the components 40. The main processor 510 may be formed as an integrated circuit. When necessary, the electronic device 1 may include not only the camera device 531 arranged on a top surface of the main circuit board 50 but also a camera device arranged on a bottom surface of the main circuit board 50. Each of the main processor 510 and the main connector 55 may be arranged on any one of the top surface and the bottom surface of the main circuit board 50. The main circuit board 50 may be electrically connected to the display circuit board 30 via the main connector 55 or the like.

The main processor 510 may control all functions of the electronic device 1. For example, the main processor 510 may output digital video data to the data driver 20 via the display circuit board 30 so that the display panel 10 displays an image. The main processor 510 may receive detection data from the touch sensor driver. The main processor 510 may determine whether the user touches according to the detection data, and may perform an operation corresponding to the user's direct touch or proximity touch. The main processor 510 may be an application processor, a central processing unit, or a system chip formed as an integrated circuit.

The camera device 531 processes an image frame such as a still image or a moving image obtained by an image sensor in a camera mode and outputs the image frame to the main processor 510. The camera device 531 may include at least one of a camera sensor (e.g., charge-coupled device (CCD) or complementary metal-oxide-semiconductor (CMOS)), a photo sensor (or image sensor), and a laser sensor.

A cable passing through the cable hole CAH of the bracket 60 may be connected to the main connector 55, and the main circuit board 50 may be electrically connected to the display circuit board 30 via the cable.

The electronic device 1 may include, although not illustrated, a wireless communication unit, an input unit, a sensor unit, an output unit, an interface unit, a memory, and/or a power supply unit, in addition to the main processor 510.

The wireless communication unit may include at least one of a broadcast receiving module, a mobile communication module, a wireless Internet module, a short-range communication module, and a location information module.

The broadcast receiving module receives a broadcast signal and/or broadcast-related information from an external broadcast management server via a broadcast channel. The broadcast channel may include a satellite channel and a terrestrial channel.

The mobile communication module transmits and receives a wireless signal to and from at least one of a base station, an external terminal, and a server in a mobile communication network established according to technical standards or communication methods for mobile communication (e.g., global system for mobile communication (GSM), code division multi-access (CDMA), code division multi-access 2000(CDMA2000 ), enhanced voice-data optimized or enhanced voice-data only (EV-DO), wideband CDMA (WCDMA), high speed downlink packet access (HSDPA), high speed uplink packet access (HSUPA), long term evolution (LTE), and long term evolution-advanced (LTE-A)). The wireless signal may include various types of data according to transmission and reception of a voice call signal, a video call signal, or a text/multimedia message.

The wireless Internet module refers to a module for wireless Internet access. The wireless Internet module may be configured to transmit and receive a wireless signal in a communication network according to wireless Internet technology. The wireless Internet technology may be, for example, wireless LAN (WLAN), Wi-Fi, Wi-Fi direct, and/or digital living network alliance (DLNA).

The short-range communication module for short-range communication may support short-range communication by using at least one of Bluetooth™, radio frequency identification (RFID), infrared data association (IrDA), ultra-wideband (UWB), ZigBee, near field communication (NFC), Wi-Fi, Wi-Fi direct, and wireless universal serial bus (USB) technology. The short-range communication module may support wireless communication between the electronic device 1 and a wireless communication system, between the electronic device 1 and another electronic device, or between the electronic device 1 and a network in which another electronic device (or an external server) is located via a wireless area network. The wireless area network may correspond to wireless personal area networks. The other electronic device may be a wearable device that may exchange data (or interoperate) with the electronic device 1.

The location information module for obtaining a location of the electronic device 1 may include a global positioning system (GPS) module or a Wi-Fi module.

The input unit may include an image input unit such as the camera device 531 for inputting an image signal, a sound input unit such as a microphone for inputting a sound signal, and an input device for receiving information from the user. The camera device 531 processes an image frame such as a still image or a moving image obtained by the image sensor in a video call mode or a photographing mode. The processed image frame may be displayed on the display panel 10 or may be stored in the memory. The microphone processes an external sound signal into electrical voice data. The processed voice data may be used in various ways according to a function being performed (or an application being executed) in the electronic device 1.

The main processor 510 may control an operation of the electronic device 1 in response to information input via the input device. The input device may include a mechanical input means or a touch input means. The mechanical input means may include a button, a dome switch, a jog wheel, or a jog switch located on a rear surface or a side surface of the electronic device 1. The touch input means may include the touchscreen layer of the display panel 10.

The sensor unit may include one or more sensors that sense at least one of information in the electronic device 1, environment information surrounding the electronic device 1, and user information and generates a corresponding sensing signal. The main processor 510 may control the driving or operation of the electronic device 1 or may perform data processing, a function, or an operation related to an application installed in the electronic device 1. The sensor unit may be a proximity sensor, an illumination sensor, or a facial recognition sensor as described with respect to the component 40. The sensor unit may include an acceleration sensor, a magnetic sensor, a Gravity sensor (G-sensor), a gyroscope sensor, a motion sensor, an RGB sensor, an infrared (IR) sensor, a fingerprint scan sensor, an ultrasonic sensor, an optical sensor, and/or a battery gauge. In addition, the sensor unit may include an environmental sensor or a chemical sensor. The environmental sensor may be, for example, a barometer, a hygrometer, a thermometer, a radiation detection sensor, a heat detection sensor, and/or a gas detection sensor. The chemical sensor may be, for example, an electronic nose, a healthcare sensor, and/or a biometric sensor.

The output unit for generating an output related to visual, auditory, or tactile sense may include at least one of the display panel 10, a sound output unit, a haptic module, and a light output unit.

The display panel 10 displays (outputs) information processed by the electronic device 1. For example, the display panel 10 may display execution screen information of an application running on the electronic device 1, may display a user interface (UI) according to the execution screen information, or may display graphical user interface (GUI) information. The display panel 10 may include a display layer for displaying an image and a touchscreen layer for detecting a touch input of the user. Accordingly, the display panel 10 may function as one of input devices that provide an input interface between the electronic device 1 and the user and at the same time, may also function as one of output units that provide an output interface between the electronic device 1 and the user.

The sound output unit may output sound data received from the wireless communication unit or stored in the memory, in a call signal reception mode, a call mode, a recording mode, a voice recognition mode, and/or a broadcast reception mode. The sound output unit may output a sound signal related to a function (e.g., a call signal reception sound or a message reception sound) performed in the electronic device 1. The sound output unit may include a receiver and a speaker. At least one of the receiver and the speaker may be a sound generating device that is attached to the bottom of the display panel 10 and outputs sound by vibrating the display panel 10. The sound generating device may be a piezoelectric element or a piezoelectric actuator that contracts or expands according to an electrical signal, or an exciter that generates a magnetic force by using a voice coil and vibrates the display panel 10.

The haptic module generates various tactile effects that the user may feel. The haptic module may provide vibration to the user as a tactile effect. The haptic module may not only transfer a tactile effect through direct contact, but may also allow the user to feel a tactile effect through a muscle sense such as a finger or arm of the user.

The light output unit outputs a signal for notifying the occurrence of an event by using light of a light source. Examples of events occurring in the electronic device 1 may include message reception, call signal reception, missed call, alarm, schedule notification, email reception, and/or information reception via an application. A signal output from the light output unit is implemented as the electronic device 1 emits light of a single color or multiple colors from a front surface or a rear surface. The signal output may be ended when the electronic device 1 detects that the user has checked the event.

The interface unit functions as a passage with various types of external devices connected to the electronic device 1. The interface unit may include at least one of a wired/wireless headset port, an external charger port, a wired/wireless data port, a memory card port, a port for connecting a device including an identification module, an audio input/output (I/O) port, a video I/O port, and an earphone port. When an external device is connected to the interface unit, the electronic device 1 may perform appropriate control related to the connected external device.

The memory stores data that supports various functions of the electronic device 1. The memory may store a plurality of applications (application programs) driven in the electronic device 1 and a plurality of pieces of data and/or instructions for an operation of the electronic device 1. At least some of the plurality of applications may be downloaded from an external server via wireless communication. The memory may store an application for an operation of the main processor 510, and may temporarily store input/output data, for example, a phone book, a message, a still image, and/or a moving image. Also, the memory may store haptic data for vibration of various patterns provided to the haptic module and sound data related to various sounds provided to the sound output unit.

The memory may include at least one type of storage medium among a flash memory type, a hard disk type, a solid state disk (SSD) type, a silicon disk drive (SDD) type, a multimedia card micro type, a card type memory (e.g., SD or XD memory), a random-access memory (RAM), a static random-access memory (SRAM), a read-only memory (ROM), an electrically erasable programmable read-only memory (EEPROM), a programmable read-only memory (PROM), a magnetic memory, a magnetic disk, and an optical disk.

The power supply unit receives external power and/or internal power and supplies the power to each element included in the electronic device 1, under control by the main processor 510. The power supply unit may include the battery 80. Also, the power supply unit may include a connection port, and the connection port may be an example of the interface unit to which an external charger for supplying power is electrically connected to charge the battery. Alternatively, the power supply unit may charge the battery 80 in a wireless manner. The battery 80 may be arranged so as not to overlap the main circuit board 50 in the third direction (z direction). The battery 80 may be disposed in an area corresponding to the battery hole BH of the bracket 60.

The lower cover 90 may form an outer appearance of the electronic device 1 and may have an opening through which a part of the display panel 10 is exposed. The lower cover 90 has a shape whose surface corresponding to the display panel 10 is open, and may be coupled to the display panel 10. The lower cover 90 may be located opposite to the cover window 70 with the display panel 10 interposed therebetween. The lower cover 90 may be arranged under the main circuit board 50 and the battery 80. The lower cover 90 may be coupled and fixed to the bracket 60. The lower cover 90 may form an outer appearance of a bottom surface of the electronic device 1. The lower cover 90 may include plastic, metal, or both plastic and metal.

A second camera hole CMH2 through which a bottom surface of the camera device 531 is exposed may be formed in the lower cover 90. A position of the camera device 531, and positions of the first camera hole CMH1 and the second camera hole CMH2 corresponding to the camera device 531 are not limited to those illustrated in FIG. 6 and may be changed in various manners.

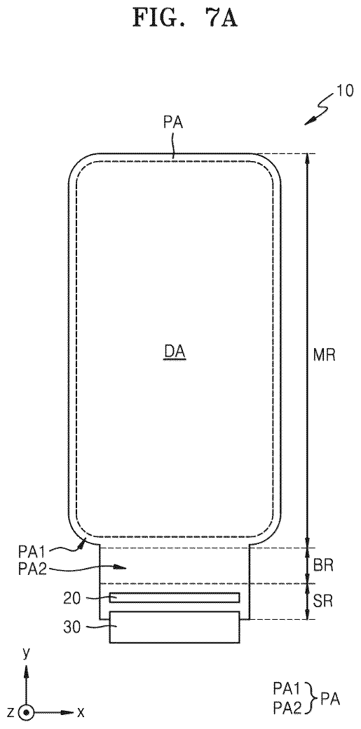

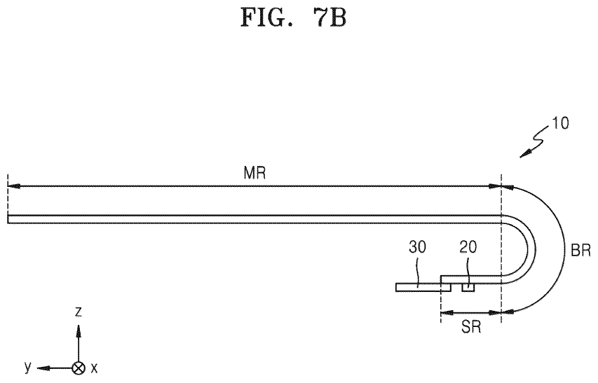

FIG. 7A is a plan view schematically illustrating a portion of the display apparatus shown in FIG. 6. FIG. 7B is a side view schematically illustrating a portion of the display apparatus shown in FIG. 7A. The electronic device 1 may include the portions of the display apparatus as shown in FIGS. 7A and 7B.

Referring to FIGS. 7A and 7B, the display apparatus may include a display panel 10, a data driver 20, and a display circuit board 30.

The display panel 10 may include a display area DA and a peripheral area PA outside the display area DA. The display area DA is a portion where an image is displayed, and a plurality of sub-pixels may be arranged in the display area DA. The display area DA may have any of various shapes such as a circular shape, an elliptical shape, a polygonal shape, and a shape of a particular figure. In FIG. 7A, the display area DA has a substantially rectangular shape with rounded corners.

The peripheral area PA may be located outside the display area DA. The peripheral area PA may include a first peripheral area PA1 surrounding at least a part of the display area DA and a second peripheral area PA2 located at a lower end of the display area DA and extending in a first direction (x-axis direction). A width of the second peripheral area PA2 in the first direction (the x-axis direction) may be less than a width of the display area DA. With this structure, at least a part of the second peripheral area PA2 may be easily bent.

A planar shape of the display panel 10 of FIG. 7A may be substantially the same as a planar shape of a substrate 100 included in the display panel 10. When the display panel 10 includes the display area DA and the peripheral area PA outside the display area DA, it may mean that the substrate 100 includes the display area DA and the peripheral area PA outside the display area DA. For convenience, it will be described that the substrate 100 includes the display area DA and the peripheral area PA. At least a portion of the planar shape of the substrate 100 corresponding to at least one of corners of the display area DA may be rounded.

The display panel 10 may include a main region MR, a bending region BR outside the main region MR, and a sub-region SR spaced apart from the main region MR with the bending region BR disposed therebetween. The main region MR may be arranged on one side of the bending region BR, and the sub-region SR may be arranged on the other side of the bending region BR. The display panel 10 may be bent in the bending region BR as shown in FIG. 7B, and the sub-region SR may overlap at least a part of the main region MR when viewed in the third direction (z-axis direction). Although FIG. 7B illustrates that the display panel 10 is bent, the disclosure is not limited thereto. For example, the display panel 10 may be a foldable display panel, and, in this case, the display panel 10 may be bent in the display area DA around a bending axis intersecting the display area DA. However, when necessary, the display panel 10 may not be bent. The sub-region SR may be a non-display area.

The data driver 20 may be arranged in the sub-region SR of the display panel 10. The data driver 20 may be arranged on a substrate forming the display panel 10 in the form of an integrated circuit (IC). For example, the data driver 20 may be a data driving integrated circuit that generates a data signal.

The display circuit board 30 may be attached to an end portion of the sub-region SR of the display panel 10. The display circuit board 30 may be electrically connected to the data driver 20 or the like via pads in the sub-region SR of the display panel 10.

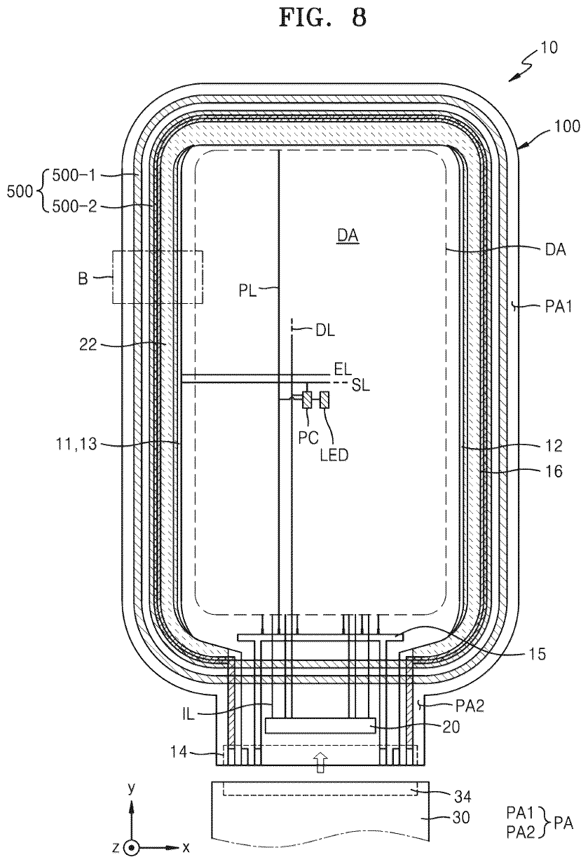

FIG. 8 is a plan view schematically illustrating a portion of the display apparatus shown in FIG. 6.

Referring to FIG. 8, the display panel 10 may include the substrate 100. Various elements included in the display panel 10 may be arranged on the substrate 100.

The substrate 100 may include glass, ceramic, metal, or polymer resin. The substrate 100 may include a polymer resin such as polyethersulfone, polyacrylate, polyetherimide, polyethylene naphthalate, polyethylene terephthalate, polyphenylene sulfide, polyarylate, polyimide, polycarbonate, and/or cellulose acetate propionate. The substrate 100 may have a multilayer structure including two layers each including the polymer resin and an inorganic layer arranged between the two layers. Alternatively, the substrate 100 may have a structure in which layers including the polymer resin and inorganic layers are alternately stacked. The inorganic layer may include, for example, silicon oxide, silicon nitride, and/or silicon oxynitride.

Sub-pixels may be arranged in the display area DA, and the display area DA may provide an image by using light emitted from the sub-pixels. Each sub-pixel may include a light-emitting diode LED that is a display element, and the light-emitting diode LED may be electrically connected to a sub-pixel circuit PC. The sub-pixel circuit PC and the light-emitting diode LED may be arranged in the display area DA. For convenience, the sub-pixel circuit PC and the light-emitting diode LED are located in parallel in FIG. 8, but, actually, the sub-pixel circuit PC and the light-emitting diode LED may at least partially overlap each other. For example, the light-emitting diode LED may be arranged on the sub-pixel circuit PC. In addition, although only one light-emitting diode LED is illustrated in FIG. 8, a plurality of light-emitting diodes LED may be provided, and the plurality of light-emitting diodes LED may be spaced apart from each other on the entire surface of the display area DA. In addition, the plurality of light-emitting diodes LED may include first group of the plurality of light-emitting diodes LED, second group of the plurality of light-emitting diodes LED and third group of the plurality of light-emitting diodes LED which emit different colors, respectively.

A gate driving circuit, a pad 14, a first power supply wiring 15, and a second power supply wiring 16 may be arranged in the peripheral area PA. The gate driving circuit may include, for example, a first scan driving circuit 11, a second scan driving circuit 12, and/or an emission control driving circuit 13.

The first scan driving circuit 11 may provide a scan signal to the sub-pixel circuit PC via a scan line SL. The second scan driving circuit 12 may be arranged opposite to the first scan driving circuit 11 with the display area DA disposed therebetween. Some of the sub-pixel circuits PC arranged in the display area DA may be electrically connected to the first scan driving circuit 11, and others may be electrically connected to the second scan driving circuit 12. When necessary, the second scan driving circuit 12 may be omitted.

The emission control driving circuit 13 may be arranged on one side of the display area DA like the first scan driving circuit 11. The emission control driving circuit 13 may provide an emission control signal to a sub-pixel via the emission control line EL. Referring to FIG. 8, it is illustrated that the emission control driving circuit 13 is arranged only on one side of the display area DA, but the disclosure is not limited thereto. For example, the display panel 10 may include the emission control driving circuits 13 arranged on one side and the other side of the display area DA. Alternatively, the first scan driving circuit 11 may be arranged on one side of the display area DA and the emission control driving circuit 13 may be arranged on the other side of the display area DA.

The pad 14 may be arranged in the second peripheral area PA2 of the substrate 100. The pad 14 may not be covered by an insulating layer and may be exposed by an insulating layer, and, thus, may be electrically connected to the display circuit board 30. A pad 34 of the display circuit board 30 may be electrically connected to the pad 14 of the display panel 10.

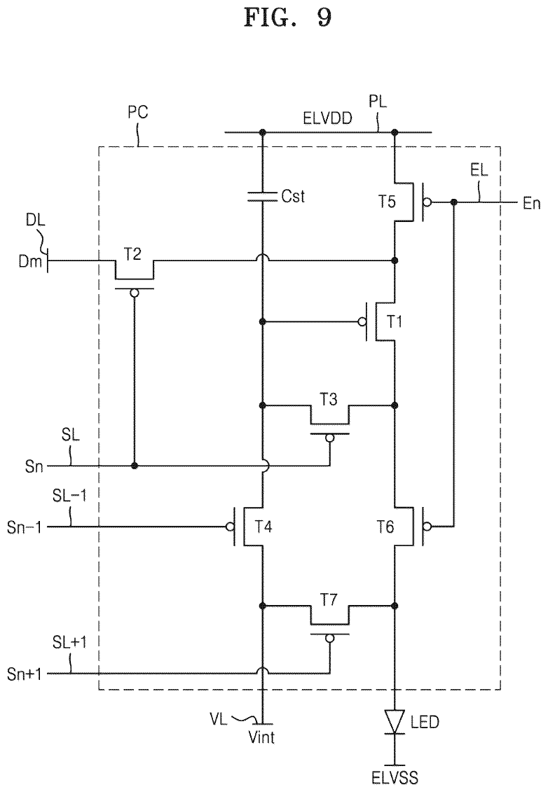

The display circuit board 30 transmits a signal or power of a controller to the display panel 10. A control signal generated by the controller may be transmitted to the gate driving circuit via the display circuit board 30. Also, the controller may provide a first power supply voltage ELVDD (see FIG. 9) and a second power supply voltage ELVSS (see FIG. 9) to the first power supply wiring 15 and the second power supply wiring 16, respectively. The first power supply voltage ELVDD (hereinafter, referred to as a driving voltage) may be provided to each sub-pixel circuit PC via a driving voltage line PL connected to the first power supply wiring 15, and the second power supply voltage ELVSS (hereinafter, referred to as a common voltage) may be provided to a common electrode of the light-emitting diode LED connected to the second power supply wiring 16. The first power supply wiring 15 may extend in the first direction (the x-axis direction). The second power supply wiring 16 may have a loop shape with one side open, and may partially surround the display area DA.

A data signal of the data driver 20 may be transmitted to the sub-pixel circuit PC via a data line DL electrically connected to the input line IL.

At least one partition wall may be arranged in the peripheral area PA. A plurality of partition walls may be provided. For example, the plurality of partition walls may include a first partition wall 500-1 and a second partition wall 500-2, which are spaced apart from each other. In this case, each of the first partition wall 500-1 and the second partition wall 500-2 may be arranged to surround the outer edge of the display area DA in an annular ring shape.

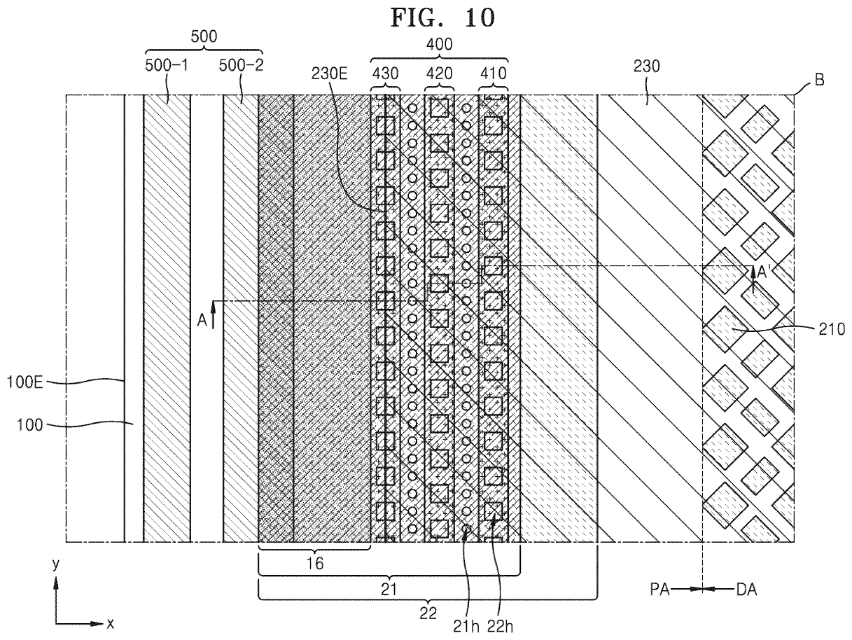

At least one conductive layer may be arranged in the peripheral area PA. In this case, at least one conductive layer may be arranged to overlap at least a portion of the second power supply wiring 16. When a plurality of conductive layers are provided, the plurality of conductive layers may include a first conductive layer 21 and a second conductive layer 22. In this case, although not illustrated in the drawings, at least one of the first conductive layer 21 and the second conductive layer 22 may have a plurality of openings, as illustrated in FIG. 10, which will be described below. In this case, the plurality of openings may be uniformly arranged through the conductive layer. For example, the plurality of openings may be arranged at regular intervals in a straight area and a curved area of the second conductive layer 22 illustrated in FIG. 8. Although the plurality of openings are not illustrated in FIG. 8, this will be described in detail with reference to FIGS. 10 to 12 below.

The second conductive layer 22 as described above may be arranged to surround a portion of the border of the display area DA. In this case, the second conductive layer 22 is not arranged in the border of the display area DA that faces the second peripheral area PA2.

FIG. 9 is a circuit diagram schematically illustrating a sub-pixel circuit of a sub-pixel arranged in a display area shown in FIG. 8.

Referring to FIG. 9, the light-emitting diode LED may be electrically connected to the sub-pixel circuit PC.

The sub-pixel circuit PC may include a first thin-film transistor T1, a second thin-film transistor T2, a third thin-film transistor T3, a fourth thin-film transistor T4, a fifth thin-film transistor T5, a sixth thin-film transistor T6, a seventh thin-film transistor T7, and a storage capacitor Cst.

The second thin-film transistor T2 that is a switching thin-film transistor may be connected to the scan line SL and the data line DL, and may transmit a data voltage (or a data signal Dm) input from the data line DL to the first thin-film transistor T1 based on a switching voltage (or a switching signal Sn) input from the scan line SL. The storage capacitor Cst may be connected to the first thin-film transistor T1 and the driving voltage line PL, and may store a voltage corresponding to a difference between a voltage received from the second thin-film transistor T2 and the first power supply voltage ELVDD supplied to the driving voltage line PL.

The first thin-film transistor T1 that is a driving thin-film transistor may be connected to the driving voltage line PL and the storage capacitor Cst, and may control driving current flowing from the driving voltage line PL to the light-emitting diode LED in response to a value of the voltage stored in the storage capacitor Cst. The light-emitting diode LED may emit light having a preset luminance according to the driving current. A second electrode (e.g., a cathode) of the light-emitting diode LED may receive the second power supply voltage ELVSS.

The third thin-film transistor T3 is a compensation thin-film transistor, and a gate electrode of the third thin-film transistor T3 may be connected to the scan line SL. A source electrode (or a drain electrode) of the third thin-film transistor T3 may be connected to a drain electrode (or a source electrode) of the first thin-film transistor T1, and may be connected to a first electrode of the light-emitting diode LED via the sixth thin-film transistor T6. The drain electrode (or the source electrode) of the third thin-film transistor T3 may be connected to one electrode of the storage capacitor Cst, a source electrode (or a drain electrode) of the fourth thin-film transistor T4, and a gate electrode of the first thin-film transistor T1. The third thin-film transistor T3 is turned on, in response to the scan signal Sn received via the scan line SL, and diode-connects the first thin-film transistor T1 by connecting the gate electrode and the drain electrode of the first thin-film transistor T1.

A gate electrode of the fourth thin-film transistor T4 that is an initialization thin-film transistor may be connected to a previous scan line SL−1. The drain electrode (or the source electrode) of the fourth thin-film transistor T4 may be connected to an initialization voltage line VL. The source electrode (or the drain electrode) of the fourth thin-film transistor T4 may be connected to the one electrode of the storage capacitor Cst, the drain electrode (or the source electrode) of the third thin-film transistor T3, and the gate electrode of the first thin-film transistor T1. The fourth thin-film transistor T4 may be turned on, in response to a previous scan signal Sn−1 received through the previous scan line SL−1, and may perform an initialization operation of initializing a voltage of the gate electrode of the first thin-film transistor T1 by supplying an initialization voltage Vint to the gate electrode of the first thin-film transistor T1.

A gate electrode of the fifth thin-film transistor T5 that is an operation control thin-film transistor may be connected to an emission control line EL. A source electrode (or a drain electrode) of the fifth thin-film transistor T5 may be connected to the driving voltage line PL. The drain electrode (or the source electrode) of the fifth thin-film transistor T5 is connected to the source electrode (or the drain electrode) of the first thin-film transistor T1 and a drain electrode (or a source electrode) of the second thin-film transistor T2.

A gate electrode of the sixth thin-film transistor T6 that is an emission control thin-film transistor may be connected to the emission control line EL. A source electrode (or a drain electrode) of the sixth thin-film transistor T6 may be connected to the drain electrode (or the source electrode) of the first thin-film transistor T1 and the source electrode (or the drain electrode) of the third thin-film transistor T3. The drain electrode (or the source electrode) of the sixth thin-film transistor T6 may be electrically connected to the first electrode of the light-emitting diode LED. The fifth thin-film transistor T5 and the sixth thin-film transistor T6 may be simultaneously turned on in response to an emission control signal En received via the emission control line EL, and thus, the first power supply voltage ELVDD is supplied to the light-emitting diode LED and driving current flows through the light-emitting diode LED.

The seventh thin-film transistor T7 may be an initialization thin-film transistor for initializing the first electrode of the light-emitting diode LED. A gate electrode of the seventh thin-film transistor T7 may be connected to a next scan line SL+1. A source electrode (or a drain electrode) of the seventh thin-film transistor T7 may be connected to the first electrode of the light-emitting diode LED. The drain electrode (or the source electrode) of the seventh thin-film transistor T7 may be connected to the initialization voltage line VL. The seventh thin-film transistor T7 may be turned on in response to a next scan signal Sn+1 received via the next scan line SL+1, and may initialize the first electrode of the light-emitting diode LED.

Referring to FIG. 9, it is illustrated that the fourth thin-film transistor T4 and the seventh thin-film transistor T7 are respectively connected to the previous scan line SL−1 and the next scan line SL+1, but, in another embodiment, both the fourth thin-film transistor T4 and the seventh thin-film transistor T7 may be connected to the previous scan line SL−1 and may be driven according to the previous scan signal Sn−1. In addition, referring to FIG. 9, it is illustrated that the fourth thin-film transistor T4 and the seventh thin-film transistor T7 are connected to the same initialization voltage line VL and receive the same initialization voltage Vint, but, in another embodiment, the fourth thin-film transistor T4 and the seventh thin-film transistor T7 may be connected to different initialization voltage lines and/or receive different initialization voltages to initialize the gate electrode of the first thin-film transistor T1 and the first electrode of the light-emitting diode LED by using different initialization voltages. Referring to FIG. 9, it is illustrated that the second thin-film transistor T2 and the third thin-film transistor T3 are connected to the same scan line SL and turned on by the same switching signal Sn, but, in another embodiment, the second thin-film transistor T2 and the third thin-film transistor T3 may be connected to different scan lines and turned on by different switching signals.

The other electrode of the storage capacitor Cst may be connected to the driving voltage line PL. The one electrode of the storage capacitor Cst may be connected to the gate electrode of the first thin-film transistor T1, the drain electrode (or the source electrode) of the third thin-film transistor T3, and the source electrode (or the drain electrode) of the fourth thin-film transistor T4.

The second electrode (e.g., cathode) of the light-emitting diode LED receives the second power supply voltage ELVSS. The light-emitting diode LED emits light according to the driving current from the first thin-film transistor T1.

The light-emitting diode LED may be an organic light-emitting diode including an organic material as a light-emitting material. In another embodiment, the light-emitting diode may be an inorganic light-emitting diode including an inorganic material as a light-emitting material. The inorganic light-emitting diode may include a PN junction diode including inorganic semiconductor-based materials. When a voltage is applied to a PN junction diode in a forward direction, holes and electrons may be injected, and energy generated by recombination of the holes and electrons may be converted into light energy to emit light of a preset color. The inorganic light-emitting diode may have a width of several to hundreds of micrometers, or several to hundreds of nanometers. In some embodiments, the light-emitting diode LED may include a quantum-dot light-emitting diode. As described above, an emission layer of the light-emitting diode LED may include an organic material, may include an inorganic material, may include quantum dots, may include an organic material and quantum dots, or may include an inorganic material and quantum dots. For convenience of descriptions, a case in which the light-emitting diode LED includes an organic light-emitting diode will be described.

Referring to FIG. 9, it is illustrated that the sub-pixel circuit PC includes seven thin-film transistors and one capacitor, but, in another embodiment, the sub-pixel circuit PC may include two or more thin-film transistors and may include two or more capacitors. Also, a circuit design of the sub-pixel circuit PC is not limited to that illustrated in FIG. 9 and may be modified in various manners.

The first to seventh thin-film transistors T1, T2, T3, T4, T5, T6, and T7 may be various types of transistors. In an embodiment, as shown in FIG. 9, all of the first to seventh thin-film transistors T1, T2, T3, T4, T5, T6, and T7 may be P-channel metal-oxide-semiconductor field-effect transistor (MOSFETs) (PMOSs). In another embodiment, at least one of the first to seventh thin-film transistors T1, T2, T3, T4, T5, T6, and T7 may be a PMOS, and others may be N-channel MOSFETs (NMOSs). In another embodiment, all of the first to seventh thin-film transistors T1, T2, T3, T4, T5, T6, and T7 may be NMOSs. Positions of sources and drains are interchangeable according to a type (a P-type or an N-type) of a transistor.

All of the first to seventh thin-film transistors T1, T2, T3, T4, T5, T6, and T7 of FIG. 9 may be transistors including a low-temperature polycrystalline silicon semiconductor. Here, the first to seventh thin-film transistors T1, T2, T3, T4, T5, T6, and T7 are not limited thereto, and at least one of the first to seventh thin-film transistors T1, T2, T3, T4, T5, T6, and T7 may be a transistor having a low-temperature polycrystalline silicon (LTPS) semiconductor layer, and others may be transistors having an oxide semiconductor layer. Alternatively, all of the first to seventh thin-film transistors T1, T2, T3, T4, T5, T6, and T7 may be transistors having an oxide semiconductor layer.

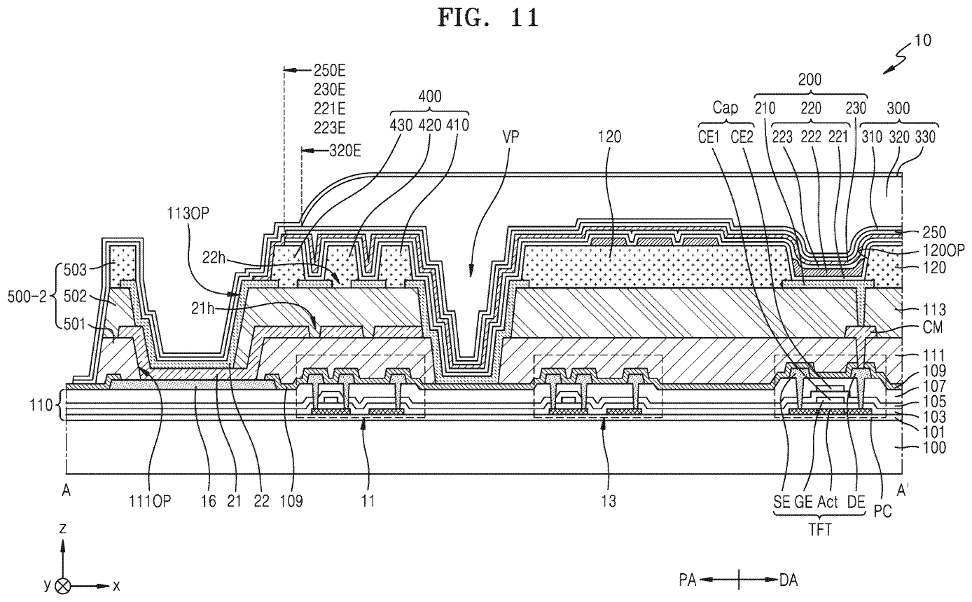

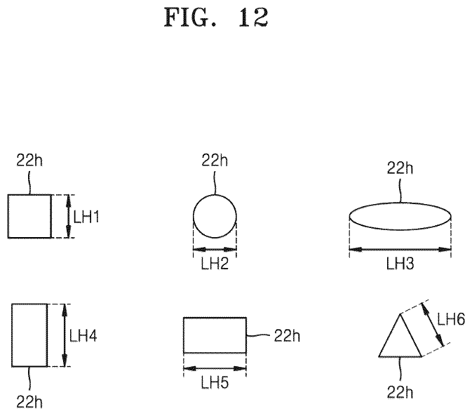

FIG. 10 is a plan view showing an enlargement of a part B of FIG. 8. FIG. 11 is a cross-sectional view taken along line A-A′ of FIG. 10. FIG. 12 is a plan view showing openings according to embodiments.

Referring to FIGS. 10 to 12, a plurality of sub-pixel electrodes 210 may be arranged in the display area DA. The plurality of sub-pixel electrodes 210 may be spaced apart from each other. Although FIG. 10 illustrates that the plurality of sub-pixel electrodes 210 are arranged in a pentile type, but the disclosure is not limited thereto. The plurality of sub-pixel electrodes 210 may be arranged in, for example, a real stripe type, an s-stripe type, or a diamond type. Although not illustrated in FIG. 10, a plurality of emission layers 222 (see FIG. 11) may be arranged to overlap each other on the plurality of sub-pixel electrodes 210.

An opposite electrode 230 may be arranged on the plurality of sub-pixel electrodes 210 and the plurality of emission layers 222. The opposite electrode 230 may overlap the entire display area DA and may extend from the display area DA to the peripheral area PA. An edge 230E of the opposite electrode 230 may be located in the peripheral area PA.

An uneven layer 400 may be arranged in the peripheral area PA and may include one or a plurality of uneven layers. For example, the uneven layer 400 may include a first uneven layer 410, a second uneven layer 420, and a third uneven layer 430 that are spaced apart from each other and arranged in a direction from the display area DA to the peripheral area PA.

A portion of one of the first to third uneven layers 410, 420, and 430 may overlap the opposite electrode 230, and another portion of one of the first to third uneven layers 410, 420, and 430 may not overlap the opposite electrode 230.

The second power supply wiring 16, the first conductive layer 21, and the second conductive layer 22 may be arranged in the peripheral area PA. The second power supply wiring 16 may be electrically connected to the opposite electrode 230 through the first conductive layer 21 and the second conductive layer 22. In the above case, the first conductive layer 21 may be formed by the same process as a contact metal CM and may include the same material as the contact metal CM. In addition, the second conductive layer 22 may be formed by the same process as the sub-pixel electrode 210 and may include a material that is the same as or similar to that of the sub-pixel electrode 210. For example, the second conductive layer 22 may include ITO, Ag and ITO layers that are sequentially stacked.

The opposite electrode 230 may be electrically connected to the second conductive layer 22 while overlapping a portion of the second conductive layer 22. Another portion of the second conductive layer 22 may be arranged to overlap the first conductive layer 21 and may be electrically connected to the first conductive layer 21. A portion of the first conductive layer 21 may be arranged to overlap the second power supply wiring 16 and may be electrically connected to the second power supply wiring 16. As in the structure described above, the opposite electrode 230 is electrically connected to the second power supply wiring 16 through the second conductive layer 22 and the first conductive layer 21, and may receive a common voltage ELVSS supplied from the second power supply wiring 16. The second conductive layer 22 may have a wider width than the first conductive layer 21, and the first conductive layer 21 may have a wider width than the second power supply wiring 16.

The first conductive layer 21 may have a plurality of first openings 21h, and the second conductive layer 22 may have a plurality of second openings 22h. The plurality of first openings 21h may provide a path for discharging gas included in an organic insulating layer (e.g., a first organic insulating layer 111) under the first conductive layer 21, and may prevent the first conductive layer 21 from being lifted from the first organic insulating layer 111. Similarly, the plurality of second openings 22h may provide a path for discharging gas included in an organic insulating layer (e.g., a second organic insulating layer 113) under the second conductive layer 22, and may prevent the second conductive layer 22 from being lifted from the second organic insulating layer 113. Although FIG. 10 illustrates a case where the plurality of first openings 21h are circular and the plurality of second openings 22h are square, the disclosure is not limited thereto. The shapes of the plurality of first openings 21h and the plurality of second openings 22h may be variously modified.

Each of the plurality of first openings 21h and/or each of the plurality of second openings 22h as described above may be polygonal, circular or elliptical. In this case, because the first opening 21h is identical or similar to the second opening 22h, the following description will focus on the second opening 22h.

The planar shape of the second opening 22h may be polygonal, circular or elliptical as illustrated in FIG. 12. In this case, when the second opening 22h is polygonal, a longest width of the planar shape of the second opening 22 h may be in a range of more than 0 μm and 40 μm or less. For example, when the planar shape of the second opening 22h is a square, a first length LH1 of the longest side may be in a range of more than 0 μm and 40 μm or less, when the planar shape of the second opening 22h is a rectangle, a fourth length LH4 or a fifth length LH5 of the longest side may be in a range of more than 0 μm and 40 μm or less, or when the planar shape of the second opening 22 h is a triangle, a sixth length LH6 of the longest side may be in a range of more than 0 μm and 40 μm or less. When the second conductive layer 22 does not have the second opening 22 h, the second conductive layer 22 may bulge due to gas, etc., from the second organic insulating layer 113 arranged under the second conductive layer 22. In addition, when the length of the largest side of the planar shape of the second opening 22 h of the second conductive layer 22 exceeds 40 μm, when the uneven layer 400 arranged on the upper side of the second conductive layer 22 is formed, the second conductive layer 22 may be separated from the second organic insulating layer 113 arranged under the second conductive layer 22 and lifted due to shrinkage of the uneven layer 400.

When the second opening 22h is circular, a second length LH2, which is the diameter thereof, may be in a range of more than 0 μm and 40 μm or less, and when the second opening 22h is elliptical, a similar effect may occur even when a third length LH3 of the major axis of the ellipse is in a range of more than 0 μm and 40 μm or less.

The first to third uneven layers 410, 420, and 430 may overlap the plurality of second openings 22h, respectively. For example, as illustrated in FIG. 10, the plurality of second openings 22h may be arranged in three rows in an extension direction of an edge 100E of the substrate 100, and each row of the plurality of second openings 22h may be covered by one uneven layer.

For example, the plurality of first openings 21h may be arranged between the plurality of second openings 22h. The plurality of first openings 21h may be arranged in rows between a plurality of rows formed by the plurality of second openings 22h. FIG. 10 illustrates the plurality of first openings 21h arranged in two rows.

The second partition wall 500-2 may be closer to the edge 100E of the substrate 100 than the uneven layer 400, the opposite electrode 230, and the plurality of sub-pixel electrodes 210. The second partition wall 500-2 may surround the display area DA in a plan view. The second partition wall 500-2 may overlap a portion of each of the second power supply wiring 16, the first conductive layer 21, and the second conductive layer 22.

The display panel 10 may have the substrate 100. The substrate 100 may include glass, ceramic, metal, or polymer resin. When the substrate 100 is flexible or bendable, the substrate 100 may include a polymer resin such as polyethersulphone, polyacrylate, polyetherimide, polyethylene naphthalate, polyethylene terephthalate, polyphenylene sulfide, polyarylate, polyimide, polycarbonate, and/or cellulose acetate propionate. For example, the substrate 100 may have a multilayer structure including two layers each including the polymer resin and an inorganic layer including an inorganic material interposed between the two layers. For example, the inorganic layer may include an inorganic material such as silicon oxide, silicon nitride, and/or silicon oxynitride.

A buffer layer 101 may be formed on the substrate 100. The buffer layer 101 may block foreign materials or moisture penetrating through the substrate 100. For example, the buffer layer 101 may include an inorganic material, such as silicon oxide (SiOₓ), silicon nitride (SiNₓ), and/or silicon oxynitride (SiON), and may be formed as a single layer or a multilayer.

On the substrate 100, thin-film transistors TFT and a storage capacitor Cap, and an organic light-emitting diode that is a light-emitting element 200 electrically connected thereto may be arranged at a position corresponding to the display area DA. The thin-film transistor TFT shown in FIG. 11 may correspond to the sixth thin-film transistor T6 described above with reference to FIG. 9, and the storage capacitor Cap shown in FIG. 11 may correspond to the storage capacitor Cst described above with reference to FIG. 9.

Each of the thin-film transistor TFT may include a semiconductor layer Act, a gate electrode GE overlapping a channel region of the semiconductor layer Act, and a source electrode SE and a drain electrode DE respectively connected to a source region and a drain region of the semiconductor layer Act.

The semiconductor layer Act may include polysilicon. In some embodiments, the semiconductor layer Act may include amorphous silicon. In some embodiments, the semiconductor layer Act may include an oxide of at least one material selected from the group consisting of indium (In), gallium (Ga), stannum (Sn), zirconium (Zr), vanadium (V), hafnium (Hf), cadmium (Cd), germanium (Ge), chromium (Cr), titanium (Ti), and zinc (Zn). The semiconductor layer Act may include the channel region and the source region and the drain region doped with impurities.

The gate electrode GE may include a low-resistivity conductive material such as molybdenum (Mo), aluminum (Al), copper (Cu), and/or titanium (Ti), and may have a single-layer or multilayer structure including the aforementioned materials.

The source electrode SE or the drain electrode DE may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single-layer or multilayer structure including the aforementioned materials. For example, the source electrode SE or the drain electrode DE may have a three-layer structure including titanium layer/aluminum layer/titanium layer. The source electrode SE and the drain electrode DE may be arranged on the same layer.

In order to secure insulation between the semiconductor layer Act and the gate electrode GE, a gate insulating layer 103 may be arranged between the semiconductor layer Act and the gate electrode GE. The gate insulating layer 103 may include an inorganic insulating material, such as silicon oxide, silicon nitride, silicon oxynitride, aluminum oxide, titanium oxide, tantalum oxide, or hafnium oxide. The gate insulating layer 103 may be a single layer or multilayer including the aforementioned materials.

The storage capacitor Cap may include a lower electrode CE1 and an upper electrode CE2 overlapping each other with a first interlayer insulating layer 105 disposed therebetween. In an embodiment, the storage capacitor Cap may overlap a thin-film transistor TFT, and the gate electrode GE of the thin-film transistor TFT may function as the lower electrode CE1 of the storage capacitor Cap. In another embodiment, the storage capacitor Cap may not overlap the thin-film transistor TFT. The storage capacitor Cap may be covered with a second interlayer insulating layer 107. The upper electrode CE2 of the storage capacitor Cap may include a conductive material including molybdenum (Mo), aluminum (Al), copper (Cu), titanium (Ti), or the like, and may be formed as a multilayer or single layer including the aforementioned materials.

The first interlayer insulating layer 105 and the second interlayer insulating layer 107 may be arranged on the gate insulating layer 103 and may include an inorganic insulating material such as silicon oxide, silicon nitride, or silicon oxynitride. The first interlayer insulating layer 105 and the second interlayer insulating layer 107 may each be a single layer or multilayer including the aforementioned materials.

The first organic insulating layer 111 may be arranged on the second interlayer insulating layer 107. The first organic insulating layer 111 may include an organic insulating material, and the organic insulating material may include an imide-based polymer, a general-purpose polymer such as polymethylmethacrylate (PMMA) or polystylene (PS), a polymer derivative having a phenol-based group, an acrylic-based polymer, an aryl ether-based polymer, an amide-based polymer, a fluorine-based polymer, a p-xylene-based polymer, a vinyl alcohol-based polymer, a blend thereof, or the like. In an embodiment, the first organic insulating layer 111 may include polyimide.

The second organic insulating layer 113 may be arranged on the first organic insulating layer 111. The second organic insulating layer 113 may include an imide polymer, a general-purpose polymer such as PMMA or PS, a polymer derivative having a phenol-based group, an acrylic-based polymer, an aryl ether-based polymer, an amide-based polymer, a fluorine-based polymer, a p-xylene-based polymer, a vinyl alcohol-based polymer, a blend thereof, or the like. In an embodiment, the second organic insulating layer 113 may include polyimide.

A sub-pixel electrode 210 may be arranged on the second organic insulating layer 113. The sub-pixel electrode 210 may include a light-transmitting conductive layer formed of a light-transmitting conductive oxide such as ITO, In₂O₃, or IZO, and a reflective layer formed of a metal such as Al or Ag. For example, the sub-pixel electrode 210 may have a three-layer structure including ITO/Ag/ITO layers. The sub-pixel electrode 210 may be connected to the contact metal CM through a contact hole formed in the second organic insulating layer 113, and the contact metal CM may be electrically connected to the thin-film transistor TFT by contacting one of the source electrode SE and the drain electrode DE through a contact hole formed in the first organic insulating layer 111. That is, the sub-pixel electrode 210 may be electrically connected to the thin-film transistor TFT through the contact metal CM.

A bank layer 120 may be arranged on the sub-pixel electrode 210, and the bank layer 120 may have an opening corresponding to each sub-pixel, that is, an opening 120OP that exposes at least a central portion of the sub-pixel electrode 210, thereby defining an emission area of the sub-pixel. In addition, the bank layer 120 may prevent arcs and the like from occurring between the edge of the sub-pixel electrode 210 and the opposite electrode 230 by increasing the distance therebetween. For example, the bank layer 120 may include an organic material, such as polyimide or hexamethyldisiloxane (HMDSO).

An intermediate layer 220 may be arranged on the bank layer 120. The intermediate layer 220 may be arranged between the sub-pixel electrode 210 and the opposite electrode 230.

The intermediate layer 220 may include an emission layer 222 formed to correspond to the sub-pixel electrode 210. The emission layer 222 may include an organic emission material such as a high-molecular weight or low-molecular weight organic material that emits light of a certain color. Alternatively, the emission layer 222 may include an inorganic emission material or quantum dots.

A first functional layer 221 and a second functional layer 223 may be arranged below and above the emission layer 222, respectively. The first functional layer 221 may be a single layer or multilayer. For example, the first functional layer 221 may be a hole transport layer (HTL) having a single-layer structure and may include poly-(3,4-ethylene-dioxy thiophene) (PEDOT) or polyaniline (PANI). Alternatively, the first functional layer 221 may include a hole injection layer (HIL) and an HTL. The second functional layer 223 may be a single layer or multilayer. The second functional layer 223 may include an electron transport layer (ETL) and/or an electron injection layer (EIL).

The emission layer 222 of the intermediate layer 220 may be arranged for each sub-pixel, while the first functional layer 221 and the second functional layer 223 may each be integrally formed as a single body to cover a plurality of sub-pixels. That is, the first functional layer 221 and the second functional layer 223 may each be a common layer. The first functional layer 221 and the second functional layer 223 may extend from the display area DA to the peripheral area PA.

The opposite electrode 230 may be arranged on the intermediate layer 220 and may be arranged to cover the display area DA. That is, the opposite electrode 230 may be integrally formed as a single body to cover a plurality of sub-pixels. The opposite electrode 230 may extend from the display area DA to the peripheral area PA. The opposite electrode 230 may include a conductive material having a low work function. For example, the opposite electrode 230 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), and/or an alloy thereof. Alternatively, the opposite electrode 230 may further include a layer including ITO, IZO, ZnO, and/or In₂O₃ on the (semi-)transparent layer including the aforementioned materials.

A stacked structure including the sub-pixel electrode 210, the intermediate layer 220, and the opposite electrode 230 may form an organic light-emitting diode as the light-emitting element 200. The organic light-emitting diode, which is a light-emitting diode, may emit red, green, or blue light. The opening 120OP of the bank layer 120 may define the size and/or width of an emission area.

A capping layer 250 may be formed on the opposite electrode 230. The capping layer 250 may include an organic insulating material and/or an inorganic insulating material such as silicon nitride. In some embodiments, the capping layer 250 may be omitted. The capping layer 250 may cover the display area DA and may extend from the display area DA to the peripheral area PA.

A thin-film encapsulation layer 300 may cover the light-emitting element 200 and may prevent the light-emitting element 200 from being damaged by moisture or oxygen from the outside. The thin-film encapsulation layer 300 may cover the display area DA and may extend from the display area DA to the peripheral area PA. This thin-film encapsulation layer 300 may include at least one inorganic encapsulation layer and at least one organic encapsulation layer. FIG. 11 illustrates a case where the thin-film encapsulation layer 300 includes a first inorganic encapsulation layer 310, an organic encapsulation layer 320, and a second inorganic encapsulation layer 330.

The first inorganic encapsulation layer 310 may cover the opposite electrode 230 and may include silicon oxide, silicon nitride, and/or silicon oxynitride. Because the first inorganic encapsulation layer 310 is formed along a profile underneath the first inorganic encapsulation layer 310, the upper surface of the first inorganic encapsulation layer 310 may not be flat. The organic encapsulation layer 320 may cover the first inorganic encapsulation layer 310 and, unlike the first inorganic encapsulation layer 310, the upper surface of the organic encapsulation layer 320 may be made approximately flat. Specifically, the organic encapsulation layer 320 may have an upper surface approximately flat in a portion thereof corresponding to the display area DA. The organic encapsulation layer 320 may include a polymer-based material. The polymer-based material may include acrylic resin, epoxy resin, polyimide, polyethylene, or the like. The acrylic resin may include, for example, polymethyl methacrylate, polyacrylic acid, or the like. The organic encapsulation layer 320 may be transparent. The second inorganic encapsulation layer 330 may cover the organic encapsulation layer 320 and may include silicon oxide, silicon nitride, and/or silicon oxynitride.

The first and second inorganic encapsulation layers 310 and 330 may be formed by chemical vapor deposition (CVD), and the organic encapsulation layer 320 may be formed by a process of applying a liquid-type organic material on the substrate 100 and then curing the liquid-type organic material.

Referring to the peripheral area PA of FIG. 11, an inorganic insulating layer 110 may be arranged on the substrate 100, and the inorganic insulating layer 110 may include the buffer layer 101, the gate insulating layer 103, and the first and second interlayer insulating layers 105 and 107, described above. A second power supply wiring 16 may be arranged on the inorganic insulating layer 110. The second power supply wiring 16 may include the same material as the source electrode SE and/or the drain electrode DE.

A portion of the upper surface of the second power supply wiring 16 may be exposed by a first opening 111OP of the first organic insulating layer 111 arranged on the second power supply wiring 16. The upper surface of the second power supply wiring 16 exposed through the first opening 111OP may be in direct contact with the first conductive layer 21 arranged on the first organic insulating layer 111. The first conductive layer 21 may be in direct contact with the second power supply wiring 16 through the first opening 111OP of the first organic insulating layer 111.

The edge or side of the second power supply wiring 16 may be covered by a protective layer 109. The protective layer 109 may prevent the second power supply wiring 16, which includes a metal (e.g., aluminum) that may be damaged by an etchant during a process of manufacturing the display panel 10, from being exposed to an etchant. In the peripheral area PA other than the area illustrated in FIG. 11, the second power supply wiring 16 may be exposed without being covered by the first organic insulating layer 111, and the exposed second power supply wiring 16 may be damaged from the side thereof by an etchant used in a process after the second power supply wiring 16 is formed. To prevent this, the protective layer 109 may cover and protect the side of the second power supply wiring 16.

The protective layer 109 may cover the thin-film transistor TFT in the display area DA. The protective layer 109 may include, for example, silicon nitride (SiNₓ). Hydrogen included in the silicon nitride may combine with a dangling bond of a semiconductor layer of a thin-film transistor and remove a defect site in the semiconductor layer, thereby improving the characteristics of the thin-film transistor.

The first conductive layer 21 may be arranged on the first organic insulating layer 111 and may be in direct contact with the upper surface of the second power supply wiring 16 through the first opening 111OP. The first conductive layer 21 may include a conductive material including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof.

The first conductive layer 21 may have a plurality of first openings 21h. For example, a portion of the first conductive layer 21, which overlaps the first organic insulating layer 111, may have a plurality of first openings 21h, and a portion of the first conductive layer 21, which directly contacts the second power supply wiring 16, may not have a first opening 21h to increase a contact area. The first conductive layer 21 may be covered with the second organic insulating layer 113, and a portion of the upper surface of the first conductive layer 21 may be exposed through a second opening 113OP of the second organic insulating layer 113. The exposed upper surface of the first conductive layer 21 may be in direct contact with the second conductive layer 22 and may be electrically connected thereto.

The second conductive layer 22 may be arranged on the second organic insulating layer 113 and may be in direct contact with the upper surface of the first conductive layer 21 through the second opening 113OP. The second conductive layer 22 may include the same material as the sub-pixel electrode 210. For example, the second conductive layer 22 may include three layers of ITO/Ag/ITO layers.

The second conductive layer 22 may have a plurality of second openings 22h. For example, a portion of the second conductive layer 22, which overlaps the second organic insulating layer 113, may have a plurality of second openings 22h, and a portion of the second conductive layer 22, which directly contacts the first conductive layer 21, may not have a second opening 22h to increase a contact area.

When the planar shapes of the plurality of first openings 21h of the first conductive layer 21 and the plurality of second openings 22h of the second conductive layer 22 are each polygonal, the longest side of the planar shape of the first opening 21h and/or the longest side of the planar shape of the second opening 22 h may be in a range of more than 0 μm and 40 μm or less. In another embodiment, when the planar shapes of the plurality of first openings 21h of the first conductive layer 21 and the plurality of second openings 22h of the second conductive layer 22 are each circular, the diameter of the planar shape of the first opening 21h and/or the diameter of the planar shape of the second opening 22h may be in a range of more than 0 μm and 40 μm or less. In another embodiment, when the planar shapes of the plurality of first openings 21h of the first conductive layer 21 and the plurality of second openings 22h of the second conductive layer 22 are each elliptical, the length of the major axis of the planar shape of the first opening 21h and/or the length of the major axis of the planar shape of the second opening 22h may be in a range of more than 0 μm and 40 μm or less. In this case, the plurality of first openings 21h of the first conductive layer 21 and the plurality of second openings 22h of the second conductive layer 22 may each provide a passage through which outgassing gas from the insulating layers (i.e., the first organic insulating layer 111 and the second organic insulating layer 113) located below the first conductive layer 21 and the second conductive layer 22 are vaporized and discharged to the outside. In addition, the plurality of first openings 21h of the first conductive layer 21 and the plurality of second openings 22h of the second conductive layer 22 may each prevent the first conductive layer 21 and the second conductive layer 22 from being lifted due to shrinkage of the second organic insulating layer 113 on the first conductive layer 21 and the bank layer 120 on the second conductive layer 22. That is, after the bank layer 120 is formed on the sub-pixel electrode 210, a thermal process (e.g., a curing process) may be performed, and a portion of a material included in the second organic insulating layer 113 or the first organic insulating layer 111 located below the second conductive layer 22 may be vaporized by the heat applied during the thermal process and discharged to the outside through the first openings 21h and/or the second openings 22h. In addition, shrinkage of the second organic insulating layer 113 or the bank layer 120 on each of the first conductive layer 21 and the second conductive layer 22 may occur. Accordingly, in the case where there is no first opening 21h and second opening 22h, the gas generated in the organic insulating layer may move toward the light-emitting element 200 and affect the light-emitting element 200 of a sub-pixel arranged at the edge of the display area DA, thereby the first opening 21h and the second opening 22h may prevent the problem of light not being emitted from the light-emitting element 200. In addition, a tensile stress caused by a shrinkage of the second organic insulating layer 113 or the bank layer 120 may be released by first opening 21h and the second opening 22h, the problem of the first conductive layer 21 being lifted from the first organic insulating layer 111 or the second conductive layer 22 being lifted from the second organic insulating layer 113 may be prevented.

The edge of the second conductive layer 22 may be covered with the bank layer 120 or an insulating layer including the same material as the bank layer 120. In addition, the plurality of second openings 22h of the second conductive layer 22 and the edges of the second openings 22h respectively surrounding the plurality of second openings 22h may be covered with the first to third uneven layers 410, 420, and 430. The first to third uneven layers 410, 420, and 430 may include the same material as the bank layer 120 and may be formed in the same mask process as the bank layer 120. The bank layer 120 and the first to third uneven layers 410, 420, and 430 may include an insulating material.

As the edge of the second conductive layer 22 and an edge surrounding the second opening 22h are both covered with an insulating material, it is possible to prevent a problem in which a portion (e.g., silver (Ag)) of the material forming the second conductive layer 22 is supplied with electrons and precipitated as silver during a process of manufacturing the display panel 10. Accordingly, it is possible to prevent a problem in which silver (Ag) is precipitated during the manufacturing process and the precipitated silver causes a defect in which a dark spot is generated by covering the edge of the second conductive layer 22 and an edge surrounding the second opening 22h with the insulating material.

The first to third uneven layers 410, 420, and 430 may be spaced apart from each other. The first to third uneven layers 410, 420, and 430 may cover the plurality of second openings 22h, respectively. For example, the first to third uneven layers 410, 420, and 430 may be spaced apart from each other in the x direction, as illustrated in FIGS. 10 and 11, and may extend in the y direction to cover the plurality of second openings 22h arranged in the y direction.

The uneven layer 400 may control the flow of the organic material of the organic encapsulation layer 320 of the thin-film encapsulation layer 300. When the organic encapsulation layer 320 is formed, the organic material forming the organic encapsulation layer 320 may flow toward the edge of the substrate 100, for example, in the-x direction. In this case, as illustrated in FIG. 11, a plurality of uneven layers 400 spaced apart from each other may obstruct the flow of the organic material, and thus, the position of the end of the organic material, that is, the position of an edge 320E of the organic encapsulation layer 320, may be controlled in the display panel 10.

The organic encapsulating layer 320 may cover at least some of the uneven layers 400. For example, the edge 320E of the organic encapsulating layer 320 may be positioned on the third uneven layer 430, as illustrated in FIG. 11. However, this is an example, and the position of the edge 320E of the organic encapsulating layer 320 may be changed depending on the type of organic material, the number and arrangement of uneven layers 400, and the interval between the uneven layers 400.

The organic encapsulating layer 320 may be formed to secure a certain thickness in the display area DA and the peripheral area PA adjacent to the display area DA. An input sensing portion including touch electrodes and an optical function layer on the input sensing portion may be arranged on the thin-film encapsulation layer 300. In order for the input sensing portion and the optical function layer to be well formed on the thin-film encapsulation layer 300, the organic encapsulation layer 320 of the thin-film encapsulation layer 300 has to be formed at a predetermined position and has to have a sufficient thickness and uniformity in a predetermined area. The thickness of the organic encapsulation layer 320 may be affected by the position of an organic material in the process of forming the organic encapsulation layer 320. When the position of the organic material, for example, the position of the edge 320E of the organic encapsulation layer 320, significantly deviates from the predetermined position, the organic material forming the organic encapsulation layer 320 quantitatively applied may not have a sufficient thickness or a uniform thickness in a certain area. Therefore, precise and accurate control of the position of the edge 320E of the organic encapsulation layer 320 is required, and, to this end, the first to third uneven layers 410, 420, and 430 may be used to confirm the position of the edge 320E of the organic encapsulation layer 320.

The common layers (i.e., the first and second functional layers 221 and 223), the opposite electrode 230, and the capping layer 250 may extend from the display area DA to the peripheral area PA, as described above, and may cover at least a portion of the uneven layer 400. Edges 221E and 223E of the common layers (i.e., the first and second functional layers 221 and 223), the edge 230E of the opposite electrode 230, and an edge 250E of the capping layer 250 may each be positioned in the peripheral area PA and may be disposed in one straight line.

A portion of each of the edges 221E, 223E, 230E, and 250E may be positioned on the uneven layer 400 and may be positioned closer to the edge of the substrate 100 than the edge 320E of the organic encapsulation layer 320. Although FIG. 11 illustrates that the edges 221E, 223E, 230E, and 250E are positioned on the third uneven layer 430, the disclosure is not limited thereto. The edges 221E, 223E, 230E, and 250E may be arranged on the first uneven layer 410 or the second uneven layer 420, may be arranged between the uneven layers 400, or may be arranged closer to the edge of the substrate 100 than the uneven layer 400, depending on a process error in the process of manufacturing the display panel 10. That is, the common layers (i.e., the first and second functional layers 221 and 223), the opposite electrode 230, and the capping layer 250 may at least partially overlap one of the uneven layers 400.

A partition wall 500 may be arranged on the outer side of the uneven layer 400, that is, at a position adjacent to the edge 100E of the substrate 100. For example, a first partition wall 500-1 and a second partition wall 500-2 may be arranged on the outer side of the uneven layer 400, that is, at a position adjacent to the edge 100E of the substrate 100. The first partition wall 500-1 and the second partition wall 500-2 may prevent an organic material from overflowing to the edge 100E of the substrate 100 when the organic encapsulation layer 320 described above is formed, thereby preventing the formation of an edge tail of the organic encapsulation layer 320. In this case, because the first partition wall 500-1 and the second partition wall 500-2 are similar to each other, for the convenience of explanation, the following description will focus on the second partition wall 500-2.

The second partition wall 500-2 may partially overlap the second power supply wiring 16, as illustrated in FIG. 11.

The second partition wall 500-2 may include a first layer 501, a second layer 502, and a third layer 503 as illustrated in FIG. 11. The first layer 501 may include the same material as the first organic insulating layer 111, the second layer 502 may include the same material as the second organic insulating layer 113, and the third layer 503 may include the same material as the bank layer 120. The second partition wall 500-2 may be arranged to completely surround the display area DA in order to prevent edge tails of the organic encapsulation layer 320. Accordingly, the second partition wall 500-2 may have a continuous ring shape completely surrounding the display area DA.

A portion of the second conductive layer 22 may be in contact with an inorganic layer. For example, a valley portion VP may be formed in the organic insulating layer arranged under the second conductive layer 22, that is, the first and second organic insulating layers 111 and 113, and a portion of the second conductive layer 22 may come into contact with an inorganic insulating layer, such as the protective layer 109, through the valley portion VP passing through the first and second organic insulating layers 111 and 113.

Because the first and second organic insulating layers 111 and 113 have a structure in which the first and second organic insulating layers 111 and 113 are disconnected at the valley portion VP, the effect of disconnecting the path of impurities that proceed through the bulk of the first and second organic insulating layers 111 and 113 may be achieved. For example, impurities generated during the process of manufacturing the display panel 10 or impurities that have penetrated after the manufacturing may proceed toward the display area DA through the bulk of the first and second organic insulating layers 111 and 113 and deteriorate a sub-pixel of the display area DA. However, because the path of impurities is disconnected by the valley portion VP, the light-emitting element 200 of the sub-pixel may be protected from the impurities.

A first scan driving circuit 11 may be located between the second power supply wiring 16 and the valley portion VP, and an emission control driving circuit 13 may be located between the valley portion VP and the sub-pixel circuit PC. The emission control driving circuit 13 and the first scan driving circuit 11 may be driver circuits that generate and control electrical signals such as an emission control signal and a scan signal, respectively. The emission control driving circuit 13 and the first scan driving circuit 11 may be formed together with the process of forming the thin-film transistors TFT, the storage capacitor Cap, and various wirings connected thereto.

Because the inorganic insulating layer 110, the protective layer 109 including an inorganic material, and the first and second inorganic encapsulation layers 310 and 330 of the thin-film encapsulation layer 300 are stacked on the end of the substrate 100, the impurities may be prevented from penetrating from the edge of the substrate 100.

Therefore, the display panel 10 may prevent the first conductive layer 21 and/or the second conductive layer 22 from being lifted. In addition, the display panel 10 may provide a clear image by reducing the disconnection or deformation of the first conductive layer 21 and/or the second conductive layer 22.

A display panel and electronic device according to embodiments may prevent a metal layer from being lifted.

A display panel and electronic device according to embodiments may reduce defects or malfunctions.

A display panel and electronic device according to embodiments may provide a clear image.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a substrate comprising a display area and a peripheral area arranged to surround at least a portion of the display area;
an insulating layer arranged on the substrate;
a conductive layer arranged on the insulating layer and extending from the display area to the peripheral area; and
an uneven layer arranged in the peripheral area and arranged on the conductive layer,
wherein the conductive layer has at least one opening, a longest width of the at least of one opening being greater than 0 μm and less than or equal to 40 μm.

2. The display panel of claim 1, wherein at least a portion of the uneven layer covers the at least one opening.

3. The display panel of claim 1, wherein the at least one opening comprises a plurality of openings, and
wherein the plurality of openings are arranged in a row along a border of the display area.

4. The display panel of claim 1, wherein the substrate comprises a round area.

5. The display panel of claim 1, further comprising a wiring arranged on the substrate and providing a common voltage.

6. The display panel of claim 5, wherein the conductive layer is electrically connected to the wiring.

7. The display panel of claim 1, further comprising:
a plurality of sub-pixel electrodes arranged on the insulating layer and spaced apart from each other in the display area;
a plurality of emission layers arranged on the plurality of sub-pixel electrodes, respectively; and
an opposite electrode arranged on the plurality of emission layers and arranged over all of the display area,
wherein the opposite electrode is electrically connected to the conductive layer.

8. The display panel of claim 1, further comprising a partition wall arranged in the peripheral area and arranged on an outer side of the uneven layer.

9. The display panel of claim 1, further comprising:
an organic insulating layer arranged in the display area; and
a bank layer arranged on the organic insulating layer and having an opening.

10. The display panel of claim 9, wherein an end of the conductive layer is disposed between the organic insulating layer and the bank layer.

11. The display panel of claim 9, wherein the uneven layer comprises a same material as the bank layer.

12. An electronic device comprising a display panel, wherein the display panel comprises:
a substrate comprising a display area and a peripheral area arranged to surround at least a portion of the display area;
an insulating layer arranged on the substrate;
a conductive layer arranged on the insulating layer and extending from the display area to the peripheral area; and
an uneven layer arranged in the peripheral area and arranged on the conductive layer,
wherein the conductive layer has at least one opening,
a longest width of the at least one opening being greater than 0 μm and less than or equal to 40 μm.

13. The electronic device of claim 12, wherein at least a portion of the uneven layer covers the at least one opening.

14. The electronic device of claim 13, wherein the at least one opening includes a plurality of openings, and
wherein the plurality of openings are arranged in a row along a border of the display area.

15. The electronic device of claim 12, wherein the substrate comprises a round area.

16. The electronic device of claim 12, wherein the display panel further comprises a wiring arranged on the substrate and providing a common voltage.

17. The electronic device of claim 16, wherein the conductive layer is electrically connected to the wiring.

18. The electronic device of claim 12, wherein the display panel further comprises:
a plurality of sub-pixel electrodes arranged on the insulating layer and spaced apart from each other in the display area;
a plurality of emission layers arranged on the plurality of sub-pixel electrodes, respectively; and
an opposite electrode arranged on the plurality of emission layers and arranged over all of the display area, and
wherein the opposite electrode is electrically connected to the conductive layer.

19. The electronic device of claim 12, wherein the display panel further comprises a partition wall arranged in the peripheral area and arranged on an outer side of the uneven layer.

20. The electronic device of claim 12, wherein the display panel further comprises a bank layer arranged on the substrate and having an opening,
wherein the uneven layer comprises a same material as the bank layer.
